(19) United States
(12) Patent Application Publication
(10) Pub. No.: US 2026/0040869 A1
(43) Pub. Date: Feb. 5, 2026

(54) METHODS TO QUICKLY ADJUST THE TEMPERATURE OF AT LEAST ONE PROCESSING LIQUID USED TO PROCESS A SEMICONDUCTOR SUBSTRATE IN A WET PROCESS

(71) Applicant: Tokyo Electron Limited, Tokyo (JP)

(72) Inventors: Shan Hu, Albany, NY (US); Peter D'Elia, Albany, NY (US); Ronald Nasman, Albany, NY (US)

(21) Appl. No.: 18/794,757

(22) Filed: Aug. 5, 2024

(51) Int. Cl. H01L 21/67

(52) U.S. Cl. CPC H01L 21/6715; H01L 21/67248; H01L 21/67253

(57) ABSTRACT

Various embodiments of wet processing systems, chemical supply systems and methods are provided herein to quickly and efficiently adjust a temperature of at least one processing liquid provided to a semiconductor substrate during a wet process. In the disclosed embodiments, processing liquid(s) flow through the chemical supply system at or near room temperature and the temperature of the processing liquid(s) is adjusted at or near the location(s) at which the processing liquid(s) are supplied to at least one surface of a semiconductor substrate (e.g., at or near the point of use) by supplying a variety of heated and/or cooled fluids to the processing liquid(s).

### TECHNICAL FIELD

The present disclosure relates to the processing of semiconductor substrates. In particular, it provides improved systems and methods for quickly adjusting the temperature of at least one processing liquid used to process a semiconductor substrate in a wet process.

### BACKGROUND

Semiconductor fabrication processes may involve a wide variety of processing steps, including depositing, growing, patterning, etching, coating, developing and cleaning steps. Some of these processing steps can be performed as wet processes using various processing liquids and chemical solutions. A wide variety of wet processing systems are known including single wafer wet processing systems, which use one or more liquid nozzles to dispense processing liquid(s) or chemical solution onto the surface of a single semiconductor substrate disposed within a process chamber, and batch processing systems which immerse a plurality (or batch) of substrates in a process tank comprising a processing liquid or chemical solution.

In wet processing systems, processing liquids and chemical solutions are typically dispensed onto one or more surfaces of a semiconductor substrate while the substrate is stationary or spinning at a predetermined rotational speed. Depending on the process being performed, the processing liquids and chemical solutions can be supplied to the substrate surface(s) at room temperature (approximately 19-23° C.), or heated (or cooled) to control the thermodynamics and kinetics of the reactions taking place on the substrate surface(s).

FIG. 1 (prior art) illustrates a conventional chemical supply system 100 that can be used to supply processing liquids and chemical solutions to a semiconductor substrate disposed within a process chamber or process tank. As shown in FIG. 1, the chemical supply system 100 includes a plurality of reservoirs 110 containing various processing liquids (e.g., liquid 1, liquid 2 . . . liquid N) that can be supplied to the substrate surface(s) separately, or mixed together in a chemical tank 120 to form a chemical solution, before the processing liquid(s) or chemical solution (hereinafter collectively referred to as “processing liquid(s)”) is/are provided to the substrate surface(s) via a liquid supply line 125.

In the chemical supply system 100, processing liquid(s) is/are circulated through a circulation loop 130 prior to supplying the processing liquid(s) to the substrate surface(s). The circulation loop 130 includes a heater 140 for heating the processing liquid(s) contained within the chemical tank 120, a pump 145 for driving the processing liquid(s) through the circulation loop 130, a filter 150 for filtering particulates from the circulating fluids and a valve 160 for: (a) selectively providing the processing liquid(s) to a process chamber or process tank via the liquid supply line 125, or (b) returning the processing liquid(s) to the chemical tank 120. Before the processing liquid(s) are supplied to the substrate surface(s), the processing liquid(s) circulated through the circulation loop 130 are gradually heated by the heater 140 until a desired chemical process temperature is achieved and maintained.

The chemical supply system 100 shown in FIG. 1 has many disadvantages. For example, it often takes an unreasonable amount of time (e.g., one or more hours) to adjust the chemical process temperature due to the heat capacities of the circulation loop 130. If a different chemical process temperature is desired, the temperature of the heater 140 is adjusted and the processing liquid(s) are recirculated through the circulation loop 130 until the new chemical process temperature is achieved. The length of time needed to adjust the chemical process temperature significantly reduces process throughput, and in some cases, may even preclude temperature adjustment during a given wet process. Some chemical supply systems may use two (or more) circulation loops when two (or more) different chemical process temperatures are needed to perform a given wet process. While this enables processing liquid(s) of different temperatures to be utilized during a given wet process, the additional circulation loop(s) increase equipment costs and maintenance concerns.

In chemical supply system 100, heated processing liquid(s) are circulated through circulation loop 130 before they are supplied to the substrate surface(s). Unfortunately, the circulation of heated processing liquid(s) presents concerns in safety, in the effectiveness of the processing liquid(s), and in durability of the equipment used to contain and circulate the processing liquid(s). As for safety, the handling of potentially harsh, caustic, and aggressive liquid or gaseous chemicals alone raises certain concerns. Heating these materials to high temperatures compounds these concerns because the materials are more volatile and prone to escaping in larger amounts into the atmosphere. Additionally, some processing liquid(s) degrade or are less effective over time due to undesired or inadvertent reactions that occur at higher temperature. Finally, some processing liquid(s) may have an adverse effect on the chemical supply system components and/or may form particulates when they are provided at higher temperature.

Accordingly, new systems and methods are needed to quickly and efficiently adjust the temperature of processing liquid(s) provided to a semiconductor substrate.

### SUMMARY

The present disclosure provides various embodiments of wet processing systems, chemical supply systems and methods to quickly and efficiently adjust a temperature of at least one processing liquid provided to a semiconductor substrate during a wet process. In the disclosed embodiments, processing liquid(s) flow through the chemical supply system at or near room temperature (e.g., about 19-23° C.) and the temperature of the processing liquid(s) is adjusted at or near the location(s) at which the processing liquid(s) are supplied to at least one surface of a semiconductor substrate (e.g., at or near the point of use) by supplying a variety of heated and/or cooled fluids to the processing liquid(s).

A wide variety of methods are used herein to quickly and efficiently adjust the temperature of the processing liquid(s) (otherwise referred to herein as the “chemical process temperature”) during a wet process. In some embodiments, a hot vapor may be supplied to, and come in contact with, the processing liquid(s) at or near the point of use to quickly and efficiently increase the chemical process temperature during the wet process. In other embodiments, a cold slurry (i.e., a mixture of frozen solids suspended in liquid) may be supplied to, and come in contact with, the processing liquid(s) at or near the point of use to quickly and efficiently decrease the chemical process temperature during the wet process. Alternatively, a hot liquid and a cold liquid may be mixed at or near the point of use to quickly and efficiently adjust the chemical process temperature during the wet process. In some embodiments, one or more of the methods disclosed herein may be combined to dynamically increase and/or decrease the chemical process temperature during a given wet process.

According to one embodiment, a method is provided herein to adjust a temperature of at least one processing liquid used to process a semiconductor substrate in a wet process. In general, the method may include providing the at least one processing liquid at a temperature at or near room temperature, dispensing the at least one processing liquid onto a surface of the semiconductor substrate, and supplying a hot vapor to the at least one processing liquid to increase the temperature of the at least one processing liquid above room temperature before or after the at least one processing liquid is dispensed onto the surface of the semiconductor substrate. The temperature of the hot vapor may be greater than or equal to its boiling point, which is higher than the temperature of the at least one processing liquid. The method may further include adjusting the temperature of the at least one processing liquid during the wet process by adjusting a flow rate of the hot vapor supplied to the at least one processing liquid.

In some embodiments, the temperature may be adjusted by increasing the flow rate of the hot vapor to increase the temperature of the at least one processing liquid. In other embodiments, the temperature may be adjusted by decreasing the flow rate of the hot vapor to decrease the temperature of the at least one processing liquid.

In some embodiments, the method may further include generating the hot vapor by heating a liquid to a boiling point of the liquid. A wide variety of liquids may be used to generate the hot vapor. When the liquid used to generate the hot vapor is water, the temperature of the hot vapor may be at least 100° C. When the liquid used to generate the hot vapor is an organic solvent, the temperature of the hot vapor may be greater than or equal to the boiling point of the organic solvent.

The at least one processing liquid may comprise a wide variety of processing liquid(s) used to process a semiconductor substrate. For the example the processing liquid may comprise an etch solution, a cleaning solution, a rinse solvent or a drying solvent. In some embodiments, the liquid used to generate the hot vapor may be the same as the at least one processing liquid. In other embodiments, the liquid used to generate the hot vapor may differ from the at least one processing liquid.

According to another embodiment, another method is provided herein to adjust a temperature of at least one processing liquid used to process a semiconductor substrate in a wet process. The method may generally include providing the at least one processing liquid at a first temperature at or near room temperature, dispensing the at least one processing liquid onto a surface of the semiconductor substrate and adjusting a temperature of the at least one processing liquid during the wet process. The temperature of the at least one processing liquid is adjusted at or near a location at which the at least one processing liquid is dispensed onto the surface of the semiconductor substrate. More specifically, the temperature of the at least one processing liquid may be adjusted by: (a) increasing the temperature of the at least one processing liquid to a second temperature, which is greater than the first temperature, during a first time period, and (b) decreasing the temperature of the at least one processing liquid to a third temperature, which is less than the first temperature or the second temperature, during a second time period. The first time period may occur before or after the second time period.

In some embodiments, the temperature of the at least one processing liquid may be adjusted by initially increasing the temperature of the at least one processing liquid during the first time period before subsequently decreasing the temperature of the at least one processing liquid during the second time period. For example, the temperature of the at least one processing liquid may be increased during the first time period by supplying a hot vapor to the at least one processing liquid. The temperature of the hot vapor may be greater than or equal to its boiling point, which is higher than the first temperature. Once combined with the at least one processing liquid, the latent heat within the hot vapor quickly and efficiently increases the temperature of the at least one processing liquid from the first temperature (e.g., room temperature) to a second temperature, which is greater than the first temperature.

In some embodiments, the temperature of the at least one processing liquid may be subsequently decreased during the second time period by: (a) decreasing the flow rate of the hot vapor to decrease the temperature of the at least one processing liquid from the second temperature to the third temperature, which is less than the second temperature, or (b) ceasing the supply of the hot vapor to the at least one processing liquid and supplying a cold slurry to the at least one processing liquid to decrease the temperature of the at least one processing liquid from the second temperature to the third temperature, which is less than the second temperature. When a cold slurry is used, the temperature of the cold slurry may be less than the second temperature to quickly and efficiently decrease the temperature of the at least one processing liquid from the second temperature to the third temperature.

In other embodiments, the temperature of the at least one processing liquid may be adjusted by initially decreasing the temperature of the at least one processing liquid during the second time period before subsequently increasing the temperature of the at least one processing liquid during the first time period. For example, the temperature of the at least one processing liquid may be initially decreased during the second time period by supplying a cold slurry to the at least one processing liquid. The temperature of the cold slurry may be less than the first temperature of the at least one processing liquid. Once combined with the at least one processing liquid, the latent heat within the cold slurry quickly and efficiently decreases the temperature of the at least one processing liquid from the first temperature (e.g., room temperature) to a third temperature, which is less than the first temperature.

In some embodiments, the cold slurry may be generated by freezing water to generate a mixture of frozen water solids suspended in water. In such embodiments, the third temperature may range between 20° C. to 0° C. In other embodiments, the cold slurry may be generated by freezing an organic solvent and water mixture to generate frozen solids of the organic solvent and water mixture suspended in the organic solvent and water mixture. In such embodiments, the third temperature may be less than or equal to 0° C. In yet other embodiments, the cold slurry may be generated by freezing an organic solvent to generate frozen solids of the organic solvent suspended in the organic solvent. In such embodiments, the third temperature may be less than 0° C.

In some embodiments, the temperature of the processing liquid(s) may be subsequently increased during the first time period by: (a) decreasing the flow rate of the cold slurry to the at least one processing liquid, or (b) ceasing the supply of the cold slurry to the at least one processing liquid and supplying a hot vapor to the at least processing liquid to increase the temperature of the at least one processing liquid from the third temperature to the second temperature, which is greater than the third temperature. The temperature of the hot vapor may be greater than or equal to its boiling point, which is higher than the third temperature to quickly and efficiently increase the temperature of the at least processing liquid from the third temperature to the second temperature.

As noted above and described further herein, the present disclosure provides various embodiments of methods for adjusting a chemical process temperature during a wet process. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) is a block diagram of a conventional chemical supply system.

FIG. 2 is a schematic diagram illustrating one example of a wet processing system that can be used to perform a wet process on a semiconductor substrate.

FIG. 3 is a block diagram illustrating a first embodiment of a chemical supply system that uses the techniques disclosed herein to quickly and efficiently adjust a temperature of at least one processing liquid dispensed onto a substrate surface during a wet process.

FIG. 4 is a block diagram illustrating a second embodiment of a chemical supply system that uses the techniques disclosed herein to quickly and efficiently adjust a temperature of at least one processing liquid dispensed onto a substrate surface during a wet process.

FIG. 5 is a block diagram illustrating a third embodiment of a chemical supply system that uses the techniques disclosed herein to quickly and efficiently adjust a temperature of at least one processing liquid dispensed onto a substrate surface during a wet process.

FIG. 6 is a block diagram illustrating a fourth embodiment of a chemical supply system that uses the techniques disclosed herein to quickly and efficiently adjust a temperature of at least one processing liquid dispensed onto a substrate surface during a wet process.

FIG. 7 is a block diagram illustrating a fifth embodiment of a chemical supply system that uses the techniques disclosed herein to quickly and efficiently adjust a temperature of at least one processing liquid dispensed onto a substrate surface during a wet process.

FIG. 8 is a block diagram illustrating a sixth embodiment of a chemical supply system that uses the techniques disclosed herein to quickly and efficiently adjust a temperature of at least one processing liquid dispensed onto a substrate surface during a wet process.

FIG. 9 is a flowchart diagram illustrating one embodiment of a method that utilizes the techniques disclosed herein to adjust a temperature of at least one processing liquid used to process a semiconductor substrate in a wet process.

FIG. 10 is a flowchart diagram illustrating another embodiment of a method that utilizes the techniques disclosed herein to adjust a temperature of at least one processing liquid used to process a semiconductor substrate in a wet process.

### DETAILED DESCRIPTION

The present disclosure provides various embodiments of wet processing systems, chemical supply systems and methods to quickly and efficiently adjust a temperature of at least one processing liquid provided to a semiconductor substrate during a wet process.

In the disclosed embodiments, processing liquid(s) flow through the chemical supply system at or near room temperature (e.g., about 19-23° C.) and the temperature of the processing liquid(s) (otherwise referred to herein as the “chemical process temperature”) is adjusted at or near the location(s) at which the processing liquid(s) are supplied to at least one surface of the semiconductor substrate (e.g., at or near the point of use) by supplying a variety of heated and/or cooled fluids to the processing liquid(s). Adjusting the chemical process temperature at or near the point of use: (a) increases throughput of the wet process by significantly reducing the length of time needed to adjust the chemical process temperature, and (b) reduces or eliminates the concerns in safety, in the effectiveness of the processing liquid(s) and in durability of the equipment used to contain and circulate the processing liquid(s) by passing room temperature processing liquid(s) through the chemical supply system components.

A wide variety of methods are used herein to quickly and efficiently adjust the temperature of the processing liquid(s) during a wet process. In some embodiments, a hot vapor may be supplied to the processing liquid(s) at or near the point of use to quickly and efficiently increase the chemical process temperature during the wet process. In other embodiments, a cold slurry (i.e., a mixture of frozen solids suspended in liquid) may be supplied to the processing liquid(s) at or near the point of use to quickly and efficiently decrease the chemical process temperature during the wet process. Alternatively, a hot liquid and a cold liquid may be mixed at or near the point of use to quickly and efficiently adjust the chemical process temperature during the wet process. In some embodiments, one or more of the methods disclosed herein may be combined to dynamically increase and/or decrease the chemical process temperature during a given wet process.

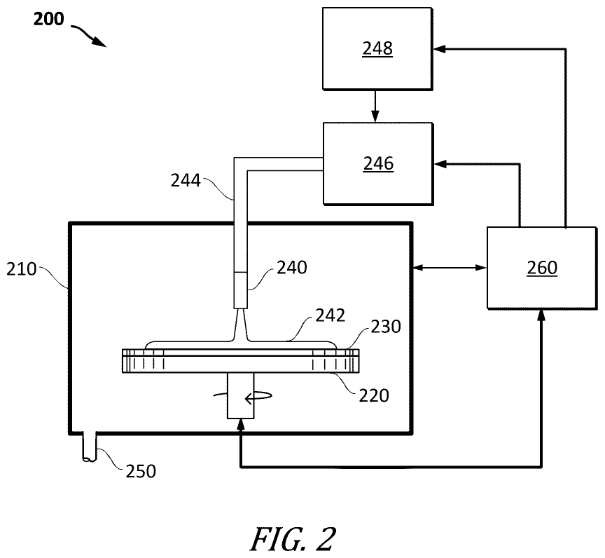

Turning now to the Drawings, FIG. 2 illustrates one embodiment of a wet processing system 200 that may utilize the techniques disclosed herein to quickly and efficiently adjust a temperature of at least one processing liquid provided to a semiconductor substrate during a wet process in accordance with the present disclosure. The wet processing system 200 shown in FIG. 2 is a spin chamber, which uses a spin chuck to rotate or spin a semiconductor substrate (or wafer) mounted onto the spin chuck, and at least one liquid nozzle for dispensing one or more processing liquids or chemical solutions onto the substrate surface while the substrate is spinning at a predetermined rotational speed. Although an example wet processing system is shown and described herein for illustrative purposes, other wet processing systems may use the techniques described herein to quickly and efficiently adjust the chemical process temperature during a wet process.

As shown in FIG. 2, the wet processing system 200 includes a process chamber 210 (or a spin chamber) having a wafer support mechanism 220 (or spin chuck), which is configured to support a semiconductor substrate 230 and spin or rotate at a rotational speed. A vacuum pressure can be applied to the wafer support mechanism 220 to hold or clamp the semiconductor substrate 230 onto the wafer support mechanism 220. Alternatively, the wafer support mechanism 220 may include other means (e.g., edge clamps) for supporting the semiconductor substrate 230.

The wet processing system 200 shown in FIG. 2 further includes at least one liquid nozzle 240, which is positioned over the semiconductor substrate 230 for dispensing at least one processing liquid 242 onto a surface of the substrate. In some embodiments, the at least one liquid nozzle 240 may be positioned above a center of the semiconductor substrate 230 for dispensing the at least one processing liquid 242 onto an upper surface of the semiconductor substrate 230 at (or very near) the center of the substrate. In other embodiments, the at least one liquid nozzle 240 may be positioned above other portions of the semiconductor substrate 230 or may be translatable across the substrate surface. In some embodiments, one or more additional liquid nozzles may be positioned below the semiconductor substrate 230 for dispensing the at least one processing liquid 242 onto a lower surface of the semiconductor substrate 230.

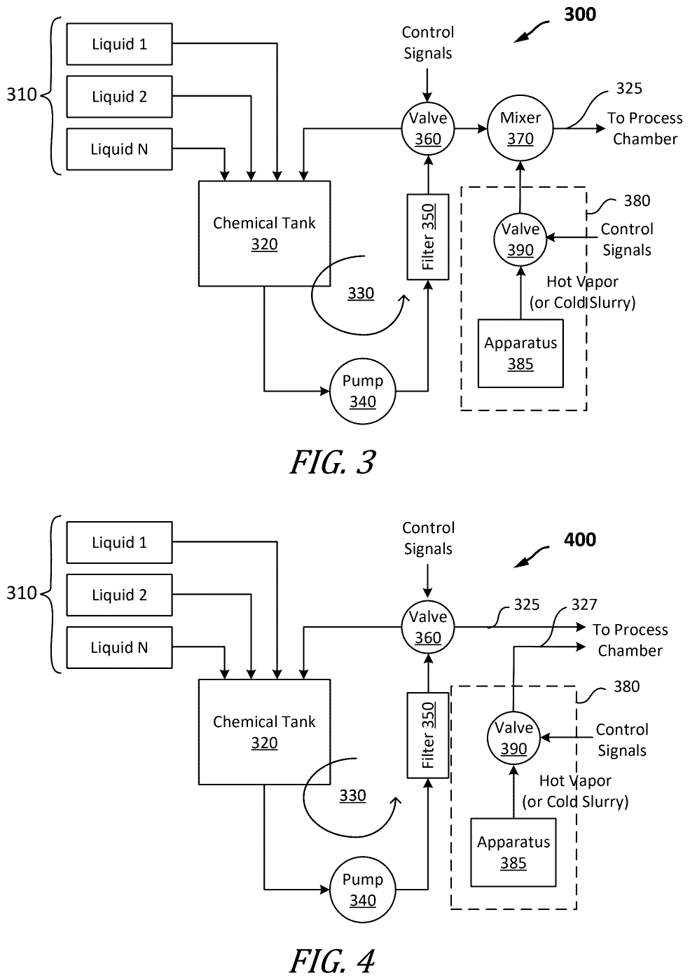

The wet processing system 200 further includes a chemical supply system 246 for storing the processing liquid(s) 242 and providing the processing liquid(s) 242 to the substrate surface(s). As shown in FIGS. 3-8 and described further herein, the chemical supply system 246 may generally include one or more reservoirs for holding various processing liquids and/or chemical solutions and a chemical injection manifold, which is fluidly coupled to the process chamber 210 via at least one liquid supply line 244. The chemical supply system 246 may include additional components, as described in more detail below. In operation, the chemical supply system 246 may selectively apply desired processing liquids and chemicals to the process chamber 210 via the liquid supply line(s) 244 and the liquid nozzle(s) 240 positioned within the process chamber 210. Thus, the chemical supply system 246 can be used to dispense the processing liquid(s) 242 onto the surface(s) of the semiconductor substrate 230. The process chamber 210 may further include a drain 250 for removing the processing liquid(s) 242 from the process chamber 210, as shown in FIG. 2.

A wide variety of processing liquid(s) 242 and chemical solutions may be dispensed from the chemical supply system 246, depending on the wet process being performed on the substrate surface. For example, the processing liquid(s) 242 dispensed onto the substrate surface(s) may include a cleaning solution when cleaning the substrate surface(s), a rinse solvent when rinsing the substrate surface(s), a drying solvent when drying the substrate surface(s) or an etch solution when etching or removing portions of the substrate or material layer(s) formed on substrate.

Examples of cleaning solutions include, but are not limited to acetone, methanol, propylene carbonate (PC), hydrofluoric acid (HF) and an ammonia/peroxide mixture (APM), a hydrochloric/peroxide mixture (HPM) and/or a sulfuric peroxide mixture (SPM). Examples of rinse solvents include, but are not limited to, deionized water and various organic solvents, such as methanol and isopropyl alcohol (IPA). Isopropyl alcohol (IPA) is one example of a drying solvent that may be used to dry a substrate surface.

A wide variety of etch solutions may be dispensed onto a substrate surface depending on the material being etched, as well as the desired etch rate and etch selectivity to other materials exposed on the substrate surface. For example, HF (in concentrated and dilute forms), a mixture of HF+nitric acid (HNO₃), potassium hydroxide (KOH) and tetramethylammonium hydroxide (TMAH) are commonly used to etch silicon (Si). On the other hand, silicon dioxide (SiO₂) is commonly etched using HF, buffered HF (a mixture of HF and ammonium fluoride (NH₄F)), or a mixture of ethylene glycol and buffered HF, while silicon nitride (SiN) is commonly etched using HF or phosphoric acid (H₃PO₄). Etch solutions containing HF can also be used to etch other material layers, such as metals, metal oxides, metal nitrides and metal silicides, as is known in the art. Other etch solutions and cleaning solutions may be used to etch other materials, as is known in the art.

In some wet processes, the processing liquid(s) 242 may be heated above room temperature before or after the processing liquid(s) 242 are dispensed onto the substrate surface. For example, certain etch solutions containing HF may be heated to a process temperature ranging between about 23° C. and 50° C. IPA, which is commonly used as a drying agent, may be used at room temperature, or at an elevated temperature (e.g., between about 23° C. and 80° C.) to increase the drying effectiveness. Other processing liquids and chemical solutions may be utilized at higher or lower chemical processing temperatures. In some cases, the chemical process temperature may be increased and/or decreased during a given wet process to better control the process by controlling the thermodynamics and kinetics of the reactions taking place on the substrate surface. For example, the chemical process temperature of an etch solution can be increased and/or decreased during the etch process to control the etch rate of material layer and/or the etch selectivity of the material layer over an underlying material layer or another material layer exposed on the substrate surface.

In the embodiments disclosed herein, a temperature control unit is included within or coupled to the chemical supply system 246 to quickly and efficiently adjust the chemical process temperature of the processing liquid(s) 242 supplied to the semiconductor substrate 230. Examples of temperature control units are shown in FIGS. 3-8. As described further herein, the temperature control unit may be configured to generate and supply hot vapor to the processing liquid(s) 242 at or near the location(s) at which the processing liquid(s) 242 are dispensed onto the substrate surface (e.g., at or near the point of use) to quickly and efficiently adjust the chemical process temperature during the wet process. The temperature control unit may be additionally or alternatively configured to generate and supply a cold slurry to the processing liquid(s) 242, or a mixture of hot and cold liquids, at or near the point of use to quickly and efficiently adjust the chemical process temperature during the wet process.

The wet processing system 200 may further include a gas supply system 248 for supplying one or more gases to the chemical supply system 246. In some embodiments, the gas supply system 248 may use a stream of hot air or nitrogen (N₂) to blow the hot vapor generated by the temperature control unit into the processing liquid(s) 242 before or after the processing liquid(s) 242 are dispensed onto the substrate surface(s).

Components of the wet processing system 200 can be coupled to, and controlled by, a controller 260, which in turn, can be coupled to a corresponding memory storage unit and user interface (not shown). Various processing operations can be executed via the user interface, and various processing recipes and operations can be stored in the memory storage unit. Accordingly, a given substrate 230 can be processed within the process chamber 210 in accordance with a particular recipe. In some embodiments, a given substrate 230 can be processed within the process chamber 210 in accordance with a process recipe that utilizes the techniques described herein to quickly and efficiently adjust the chemical process temperature during a wet process (e.g., an etch process, a cleaning process, a rinsing process, a drying process or a combination thereof).

The controller 260 shown in block diagram form in FIG. 2 can be implemented in a wide variety of manners. In one example, the controller 260 may be a computer. In another example, the controller 260 may include one or more programmable integrated circuits that are programmed to provide the functionality described herein. For example, one or more processors (e.g., a microprocessor, microcontroller, central processing unit, etc.), programmable logic devices (e.g., a complex programmable logic device (CPLD), field programmable gate array (FPGA), etc.), and/or other programmable integrated circuits can be programmed with software or other programming instructions to implement the functionality of a prescribed process recipe. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits can cause the programmable integrated circuits to perform the processes, functions, and/or capabilities described herein. Other variations could also be implemented.

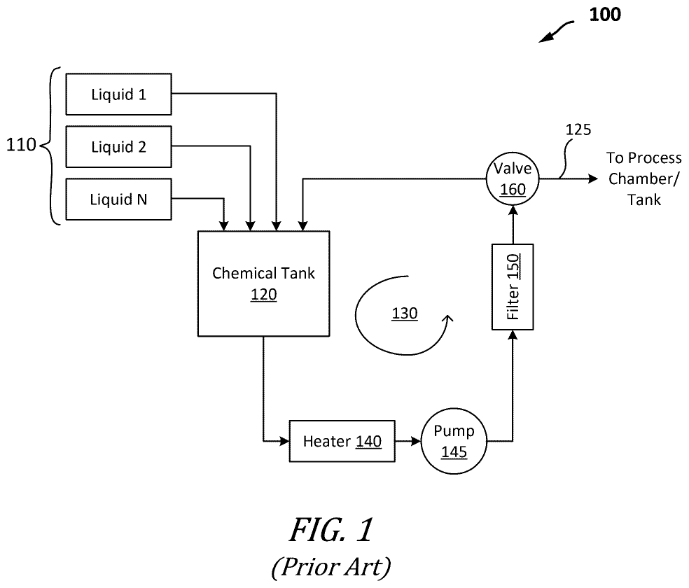

As shown in FIG. 2, the controller 260 may be coupled to various components of the wet processing system 200 to receive inputs from, and provide outputs to, the components. For example, the controller 260 may be coupled to: the process chamber 210 for controlling the temperature and/or pressure within the process chamber 210; the wafer support mechanism 220 for controlling the rotational speed of the wafer support mechanism 220; the chemical supply system 246 for controlling the processing liquid(s) 242 dispensed onto the semiconductor substrate 230, as well as the heated and/or cooled fluids supplied to the processing liquid(s) 242 by the temperature control unit; and the gas supply system 248 for controlling a gas (e.g., hot air or N₂) supplied to the chemical supply system 246 or the process chamber 210. The controller 260 may control other processing system components not shown in FIG. 1, as is known in the art.

In some embodiments, control signals supplied by the controller 260 to the temperature control unit may cause the temperature control unit to selectively supply heated and/or cooled fluids (e.g., a hot vapor, a cold slurry, a hot liquid and/or a cold liquid) to the processing liquid(s) 242 before or after the processing liquid(s) 242 are dispensed onto the substrate surface(s) by the chemical supply system 246. In some embodiments, the controller 260 may supply additional control signals to the temperature control unit that cause the temperature control unit to control or adjust the flow rate of the heated and/or cooled fluids supplied to the processing liquid(s) 242.

FIGS. 3-8 illustrate various embodiments of a chemical supply system that utilizes the techniques disclosed herein to quickly and efficiently adjust the chemical process temperature of at least one processing liquid dispensed onto at least one surface of a semiconductor substrate during a wet process. Each of the embodiments includes a plurality of reservoirs 310 containing various processing liquids (e.g., liquid 1, liquid 2 . . . liquid N) that can be supplied to the substrate surface(s) separately, or mixed together in a chemical tank 320 or a mixer 370 to form a chemical solution, before the processing liquid(s) or chemical solution (hereinafter collectively referred to as “processing liquid(s)”) is/are provided to the substrate via a liquid supply line 325 and liquid nozzle (not shown in FIGS. 3-8). The processing liquids stored within the reservoirs 310 may be provided to the chemical tank 320 or the mixer 370 at a first temperature (e.g., room temperature).

In the chemical supply system 300 shown in FIG. 3 and the chemical supply system 400 shown in FIG. 4, the processing liquid(s) is/are circulated through a circulation loop 330 prior to supplying the processing liquid(s) to a semiconductor substrate disposed within a process chamber (e.g., a spin chamber, as shown in FIG. 2). In the embodiments shown in FIGS. 3 and 4, the circulation loop 330 includes a pump 340 for driving the processing liquid(s) through the circulation loop 330, a filter 350 for filtering the circulating fluids and a valve 360 for: (a) returning the processing liquid(s) to the chemical tank 320, or (b) selectively providing the processing liquid(s) to a mixer 370 (as shown in FIG. 3) or directly to the process chamber via the liquid supply line 325 (as shown in FIG. 4).

Unlike the chemical supply system 100 shown in FIG. 1, the embodiments shown in FIGS. 3 and 4 do not include a heater for heating the processing liquid(s) circulating through the circulation loop 330. Instead, the processing liquid(s) are provided within the chemical supply systems 300/400 at a first temperature (e.g., a room temperature around 19-23° C.), and the temperature of the processing liquid(s) is adjusted by a temperature control unit 380 before or after the processing liquid(s) are dispensed onto the substrate surface(s).

The temperature control unit 380 disclosed herein includes an apparatus 385 for generating heated and/or cooled fluids and a valve 390 for selectively supplying the heated and/or cooled fluids to the processing liquid(s) before or after the processing liquid(s) are dispensed onto the substrate surface(s). In some embodiments, a controller (such as the controller 260 shown in FIG. 2) may supply control signals to the valves 360 and 390 to open/close the valves 360 and 390 to: (a) supply the heated and/or cooled fluids to the processing liquid(s) before or after the processing liquid(s) are dispensed onto the substrate surface(s), and (b) control the flow rate of the heated and/or cooled fluids supplied to the processing liquid(s).

In the chemical supply system 300 shown in FIG. 3, the heated and/or cooled fluids (e.g., a hot vapor and/or cold slurry) provided by the temperature control unit 380 are supplied to a mixer 370 where they are combined with the processing liquid(s) circulating within the circulation loop 330 and output from the valve 360. In this embodiment, the heated and/or cooled fluids adjust the temperature of the processing liquid(s) before the processing liquid(s) are dispensed onto the substrate surface(s) via the liquid supply line 325 and liquid nozzle (not shown in FIG. 3).

In the chemical supply system 400 shown in FIG. 4, the mixer 370 is omitted and the heated and/or cooled fluids (e.g., a hot vapor and/or cold slurry) are supplied directly to the substrate surface(s) via an additional liquid supply line 327 and liquid nozzle (not shown in FIG. 4). In this embodiment, the heated and/or cooled fluids mix with the processing liquid(s) on the substrate surface(s) to adjust the temperature of the processing liquid(s) after the processing liquid(s) are dispensed onto substrate surface(s).

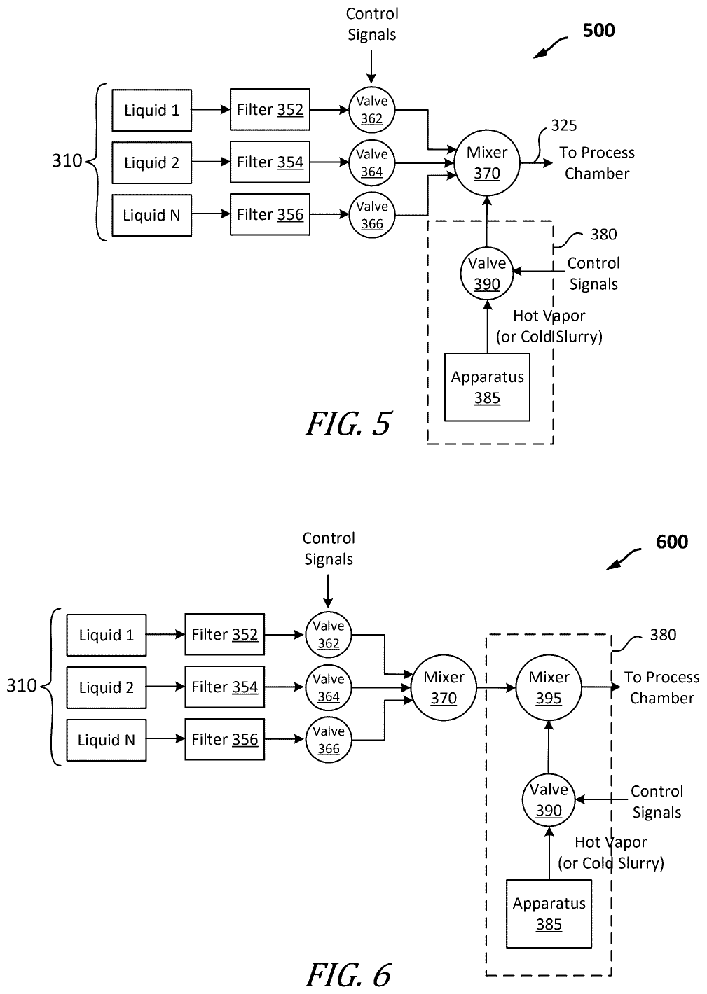

FIGS. 5-8 illustrate alternative embodiments of a chemical supply system (500, 600, 700 and 800) that does not include a circulation loop 330 as shown in FIGS. 3 and 4. In the embodiments shown in FIGS. 5-8, the processing liquids stored within the reservoirs 310 at a first temperature (e.g., room temperature) are individually filtered by a plurality of filters (e.g., 352, 354 and 356) and selectively provided to a mixer 370 by a plurality of valves (e.g., 362, 364 and 366). Control signals are supplied to the plurality of valves (e.g., 362, 364 and 366) by a controller (e.g., the controller 260 shown in FIG. 2) to selectively open/close the plurality of valves and control the processing liquid(s) supplied to the mixer 370. Additional control signals may be supplied to the valve 390 included within the temperature control unit 380 to open/close the valve 390 to: (a) supply the heated and/or cooled fluids to the processing liquid(s) before or after the processing liquid(s) are dispensed onto the substrate surface(s), and (b) control the flow rate of the heated and/or cooled fluids supplied to the processing liquid(s).

In the chemical supply system 500 shown in FIG. 5, the heated and/or cooled fluids (e.g., a hot vapor and/or cold slurry) provided by the temperature control unit 380 are supplied to the mixer 370 where they are combined with the processing liquid(s) selectively provided by the plurality of valves 362, 364 and 366. In this embodiment, the heated and/or cooled fluids adjust the temperature of the processing liquid(s) before the processing liquid(s) are dispensed onto the substrate surface(s) via the liquid supply line 325 and liquid nozzle (not shown in FIG. 5).

In the chemical supply system 600 shown in FIG. 6, the heated and/or cooled fluids (e.g., a hot vapor and/or cold slurry) provided by the temperature control unit 380 are supplied to an additional mixer 395 coupled between the output of the mixer 370 and the liquid supply line 325. This embodiment enables processing liquids to be mixed into a chemical solution before the heated and/or cooled fluids are supplied to the chemical solution to adjust the temperature of the chemical solution.

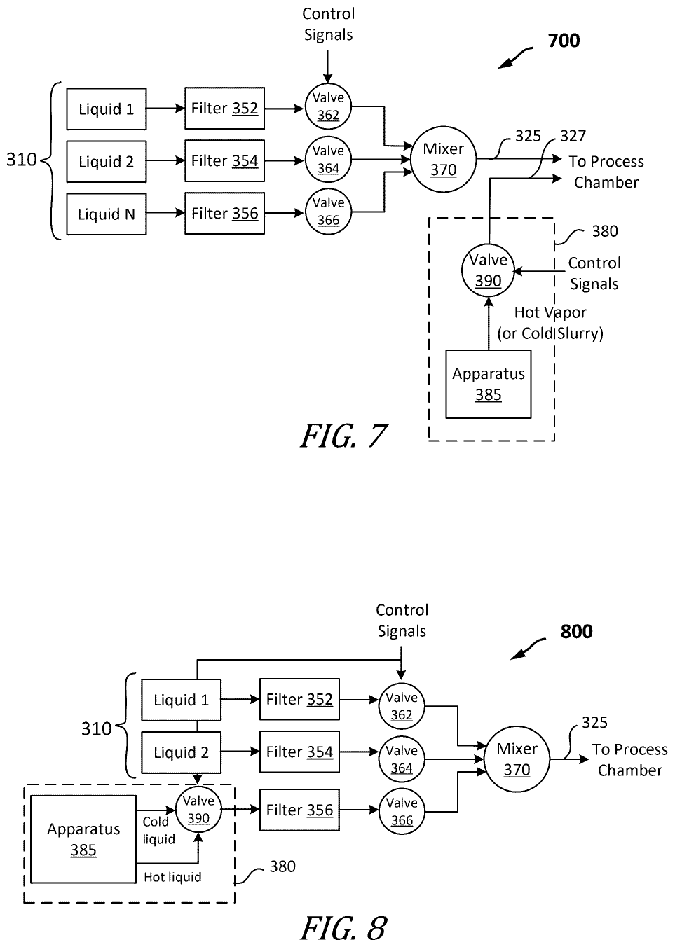

In the chemical supply system 700 shown in FIG. 7, the heated and/or cooled fluids (e.g., a hot vapor and/or cold slurry) provided by the temperature control unit 380 are supplied directly to the substrate surface(s) via an additional liquid supply line 327 and liquid nozzle (not shown in FIG. 7). In this embodiment, the heated and/or cooled fluids mix with the processing liquid(s) on the substrate surface(s) to adjust the temperature of the processing liquid(s) after the processing liquid(s) are dispensed onto substrate surface(s).

In the chemical supply system 800 shown in FIG. 8, the heated and/or cooled fluids (e.g., a hot liquid and/or cold liquid) provided by the temperature control unit 380 are filtered (e.g., by the filter 356) and provided by (e.g., the valve 366) to the mixer 370 where they are combined with one or more processing liquids selectively provided by the valves 362 and 364. In the embodiment shown in FIG. 8, the temperature of the processing liquid(s) is adjusted by controlling the flow rate of the hot/cold liquids mixed with the processing liquid(s) before the processing liquid(s) are dispensed onto the substrate surface(s).

The apparatus 385 shown in FIGS. 3-8 may be configured to generate a wide variety of heated and/or cooled fluids including, for example, a hot vapor, a cold slurry, a hot liquid and/or a cold liquid. The apparatus 385 may be implemented in a wide variety of ways, depending on the heated and/or cooled fluids being supplied to the processing liquid(s).

In some embodiments, the apparatus 385 shown in FIGS. 3-7 may be configured to generate a hot vapor by heating a liquid to the boiling point (expressed in ° C.) of the liquid using any conventional method of heating. A wide variety of liquids can be used to generate the hot vapor. For example, water, isopropyl alcohol, ethylene glycol, propylene carbonate and other liquids commonly used in semiconductor processing may be used to generate the hot vapor. The temperature of the hot vapor (expressed in ° C.) may vary, depending on the liquid used to generate the hot vapor. For example, the apparatus 385 may generate: (a) water vapor having a temperature of at least 100° C. by boiling deionized water, (b) isopropyl alcohol (IPA) vapor having a temperature of at least 82.3° C. by boiling IPA, (c) ethylene glycol (EG) vapor having a temperature of at least 197.3° C. by boiling EG, or (d) propylene carbonate (PC) vapor having a temperature of at least 242° C. by boiling PC. Other hot vapors may also be generated by the apparatus 385 by heating other liquids to the boiling point of the liquid.

The liquid used to generate the hot vapor may be the same as, or different than, the processing liquid(s) used in the wet process. For example, water vapor may be used to increase the chemical process temperature of a wide variety of room temperature aqueous and non-aqueous solvents and solutions dispensed onto the substrate surface(s) during a wide variety of wet processes (e.g., etch processes, cleaning processes, rinse processes, drying processes, etc.). In another example, IPA vapor may be used to increase the chemical process temperature of room temperature IPA dispensed onto the substrate surface(s) during a drying process.

When the hot vapor is supplied to the processing liquid(s), the latent heat of vaporization contained within the hot vapor quickly and efficiently increases the chemical process temperature from about room temperature to a desired process temperature. In some embodiments, the relatively large amount of latent heat stored within the hot vapor may enable relatively small amounts of vapor to increase the chemical process temperature without diluting the processing liquid(s).

The final chemical process temperature achieved by mixing the hot vapor with the processing liquid(s) is not solely based on the latent heat stored within the hot vapor. Instead, the final chemical process temperature (T_{final}) is dependent on the mass (m1), specific heat (c1) and initial chemical process temperature (T1) of the processing liquid(s) being heated, and the mass (m2), specific heat (c2), temperature (T2), boiling point (Tb) and latent heat of vaporization (ΔHᵥₐₚ) of the hot vapor, as expressed in EQ. 1 below.

$${T}_{final} = \frac{( m 2 \times c 2 \times ( T 2 - T b ) + Δ {H}_{vap} \times m 2 + Tb \times m 2 \times c 1 + m 1 \times c 1 \times T 1 )}{c 1 \times ( m 1 + m 2 )} \qquad EQ . 1$$

In EQ. 1, m1 and m2 are expressed in grams (g), c1 and c2 are expressed in Joules/gram ° C. (J/g ° C.), T1, T2 and Tb are expressed in ° C. and ΔHᵥₐₚ is expressed in Joules/kilogram (J/kg). In one example, a final chemical process temperature of 71.7° C. may be achieved by combining 1 gram (g) of water vapor at 100° C. (where c2=2.01 J/g ° C.) with 11 grams of liquid water at 20° C. (where c1=4.186 J/g ° C.).

In some embodiments, the apparatus 385 shown in FIGS. 3-7 may be configured to generate a cold slurry (i.e., a mixture of frozen solids suspended in liquid) by cooling a liquid to at least the freezing/melting point (expressed in ° C.) of the liquid using any conventional method of cooling. The frozen solids generated by the cooling method may be mixed with the same liquid, or a different liquid, to generate the cold slurry. As with the hot vapor embodiment, a wide variety of liquids (e.g., water, isopropyl alcohol, ethylene glycol, propylene carbonate, etc.) can be used to generate a cold slurry having a wide variety of temperatures. For example, the apparatus 385 may generate a cold slurry having: (a) a temperature of about 0° C. by freezing deionized water to generate small ice particles suspended in water, (b) a temperature range between about −89° C. and 0° C. by freezing various concentrations of IPA (e.g., 100% IPA to 0% IPA in water mixture) to generate small solids of IPA/water mixture suspended in the IPA and water mixture, (c) a temperature range between about −13° C. and 0° C. by freezing various concentrations of ethylene glycol (e.g., 100% EG to 0% EG in water mixture) to generate small solids of EG/water mixture suspended in the EG and water mixture, or (d) a temperature range between about −49° C. to about 0° C. by freezing various concentrations of propylene carbonate (e.g., 100% PC to 0% PC in water mixture) to generate small solids of PC/water mixture suspended in the PC and water mixture. Other cold slurries may be generated by cooling other liquids to at least the melting point of the liquid.

Unlike vapor, which can be heated above the boiling point of the liquid used to generate the vapor, cold slurry is a two-phase liquid in which frozen solids and liquid co-exist at an equilibrium temperature. The equilibrium temperature is the melting point of the frozen solids if the frozen solids and the liquid are the same. For example, frozen water solids (ice) and water co-exist at the melting point (0° C.) of the frozen water solids, frozen IPA solids co-exist with IPA liquid at the melting point (−89° C.) of the frozen IPA solids, and frozen solids of an organic solvent/water mixture co-exist with the same ratio of the organic solvent/water mixture between 0° C. and the melting point of the organic solvent, depending on the ratio of the organic solvent and water in the mixture. If a frozen solid is mixed with a different liquid, there will be a heat transfer between the frozen solid and the liquid until an equilibrium temperature is achieved.

In some embodiments, a cold slurry generated from deionized water may be used to quickly and efficiently decrease the chemical process temperature of a processing liquid or chemical solution below room temperature (e.g., to a temperature between about 20° C. to 0° C.). For example, the cold slurry may be generated by freezing deionized water to generate a mixture of frozen water solids suspended in deionized water. In other embodiments, a cold slurry generated from an organic solvent (such as, e.g., isopropyl alcohol, ethylene glycol, propylene carbonate, etc.) or an organic solvent and water mixture may be used to quickly and efficiently decrease the chemical process temperature of a processing liquid or chemical solution below 0° C. For example, the cold slurry may be generated by: (a) freezing an organic solvent to generate frozen solids of the organic solvent suspended in the organic solvent, or (b) freezing an organic solvent and water mixture to generate frozen solids of the organic solvent and water mixture suspended in the organic solvent and water mixture. In yet other embodiments, a cold slurry generated from deionized water, an organic solvent or another liquid commonly used in semiconductor processing may be used to quickly and efficiently decrease the chemical process temperature of a processing liquid or chemical solution that was previously heated to an elevated temperature, for example, by a hot vapor.

When the cold slurry is supplied to the processing liquid(s), the latent heat of fusion of the cold slurry quickly and efficiently decreases the chemical process temperature from about room temperature to a desired process temperature. In some embodiments, the relatively large amount of latent heat stored within the cold slurry may enable the cold slurry to quickly and efficiently decrease the chemical process temperature. However, since the latent heat of fusion is generally smaller than the latent heat of vaporization, a larger amount of slurry may be needed to decrease the chemical process temperature of the processing liquid(s). Thus, the cooling process may dilute the processing liquid(s) more than the vapor heating process.

Like the previous hot vapor example, the final chemical process temperature achieved by mixing a cold slurry with the processing liquid(s) is not solely based on the latent heat stored within the cold slurry. Instead, the final chemical process temperature (T_{final}) is dependent on the mass (m1), specific heat (c1) and initial chemical process temperature (T1) of the processing liquid(s) being cooled, the mass (m2), specific heat (c2) and temperature (T2) of the liquid within the cold slurry, the mass (m3), specific heat (c3) and temperature (T3) of the frozen solids within the cold slurry and the latent heat of fusion (ΔH_{fus}) of the frozen solids, as expressed in EQ. 2. As noted above, the temperature (T3) of the frozen solids may be the same or different from the temperature (T2) of the liquid within the cold slurry. In EQ. 2 shown below, it is assumed that T2=T3=the melting point of the frozen solid.

$${T}_{final} = \frac{( m 1 \times c 1 \times T 1 + ( m 2 + m 3 ) \times c 2 \times T 2 - m 3 \times Δ {H}_{f u s} )}{( m 2 + m 3 ) \times c 2 + m 1 \times c 1} \qquad EQ . 2$$

In EQ. 2, m1, m2 and m3 are expressed in grams (g), c1 and c2 are expressed in Joules/gram ° C. (J/g ° C.), T1 and T2 are expressed in ° C. and ΔH_{fus} is expressed in Joules/kilogram (J/kg). In one example, a final chemical process temperature of 10° C. may be achieved by combining 1 gram (g) of cold slurry comprising 90% ice (m3=0.9 g) and 10% water (m2=0.1 g) at 0° C. with 8.2 grams of liquid water at 20° C.

The apparatus 385 shown in FIG. 8 differs from those shown in FIGS. 3-7 by generating hot and cold liquids instead of a hot vapor or cold slurry. The apparatus 385 shown in FIG. 8 may use any conventional heating and/or cooling methods to generate the hot and cold liquids. In some embodiments, the apparatus 385 shown in FIG. 8 may supply relatively cold deionized water (having, e.g., a temperature between about 0° C. to about 23° C.) and/or relatively hot deionized water (having, e.g., a temperature between about 23° C. to about 100° C.) to the valve 390. Thus, in the embodiment shown in FIG. 8, the chemical process temperature of the processing liquid(s) may be adjusted by controlling the flow rate of the hot and/or cold liquids mixed with the processing liquid(s).

The chemical supply systems disclosed herein provide various advantages over conventional chemical supply systems. Instead of utilizing heater(s) to slowly adjust the chemical process temperature of circulating processing liquid(s), the chemical supply systems shown in FIGS. 3-8 use a centralized source (i.e., the temperature control unit 380) to quickly and efficiently heat and/or cool individual processing liquids, or a chemical solution comprising a mixture of processing liquids, at or near the location at which the processing liquid(s) are dispensed onto the substrate surface (i.e., at or near the point of use). By replacing the heaters used in conventional circulation loops, the temperature control unit 380 minimizes heat loss in the circulation loop 330 and avoids the need for multiple circulation loops (e.g., when different chemical process temperatures are needed to perform a given wet process). The temperature control unit 380 may also extend the lifetime of the chemical supply systems components (e.g., the pump 340, filter 350, tubing, etc.) and generate less particles by circulating the processing liquid(s) at or near room temperature.

The temperature control unit 380 utilizes the latent heat stored within a variety of heated and/or cooled fluids (e.g., a hot vapor, cold slurry, a cold liquid and a hot liquid) to quickly and efficiently adjust the temperature of the processing liquid(s) before or after the processing liquid(s) are supplied to the substrate surface(s). In some embodiments, the temperature control unit 380 may increase the temperature of the processing liquid(s) during a given wet process by supplying heated fluids (e.g., a hot vapor or hot liquid) to the processing liquid(s) at or near the point of use. In other embodiments, the temperature control unit 380 may decrease the temperature of the processing liquid(s) during a given wet process by supplying cooled fluids (e.g., a cold slurry or cold liquid) to the processing liquid(s) at or near the point of use.

In yet other embodiments, the temperature control unit 380 may adjust the temperature of the processing liquid(s) up and down during a given wet process by supplying heated and/or cooled fluids to the processing liquid(s) at different times. In one example embodiment, the temperature control unit 380 may initially increase the temperature of the processing liquid(s) to a second temperature, which is greater than the first temperature, by supplying a hot vapor to the processing liquid(s) during a first time period before subsequently decreasing the temperature of the processing liquid(s) to a third temperature, which is less than the second temperature, by reducing the flow rate of the hot vapor supplied to the processing liquid(s) during a second time period.

In another example embodiment, the temperature control unit 380 may initially increase the temperature of the processing liquid(s) to a second temperature, which is greater than the first temperature, by supplying a hot vapor to the processing liquid(s) during a first time period before subsequently decreasing the temperature of the processing liquid(s) to a third temperature, which is less than the second temperature, by supplying a cold slurry to the processing liquid(s) during a second time period. In some embodiments, the first time period and the second time period may not overlap and the hot vapor flow may be stopped before the cold slurry is supplied to the processing liquid(s). In other embodiments, the first time period and the second time period may at least partially overlap and a gradual transition may be achieved between the hot vapor and the cold slurry by steadily decreasing the flow rate of the hot vapor while increasing the flow rate of the cold slurry.

In another example embodiment, the temperature control unit 380 may initially decrease the temperature of the processing liquid(s) to a third temperature, which is less than the first temperature, by supplying a cold slurry to the processing liquid(s) during a first time period before subsequently increasing the temperature of the processing liquid(s) to a second temperature, which is greater than the third temperature, by supplying a hot vapor to the processing liquid(s) during a second time period. In some embodiments, the first time period and the second time period may not overlap and the flow of cold slurry may be stopped before the hot vapor is supplied to the processing liquid(s). In other embodiments, the first time period and the second time period may at least partially overlap and a gradual transition may be achieved between the cold slurry and the hot vapor by steadily decreasing the flow rate of the cold slurry while increasing the flow rate of the hot vapor.

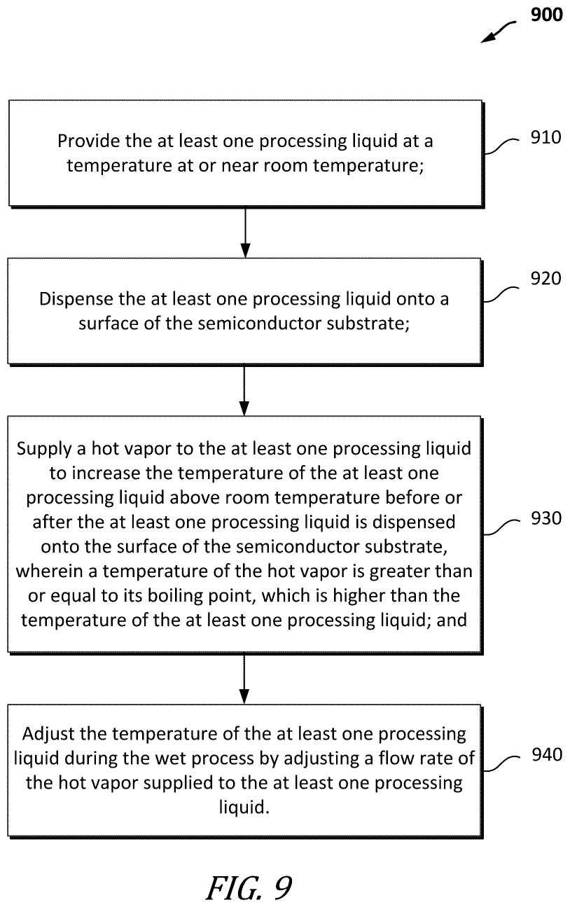

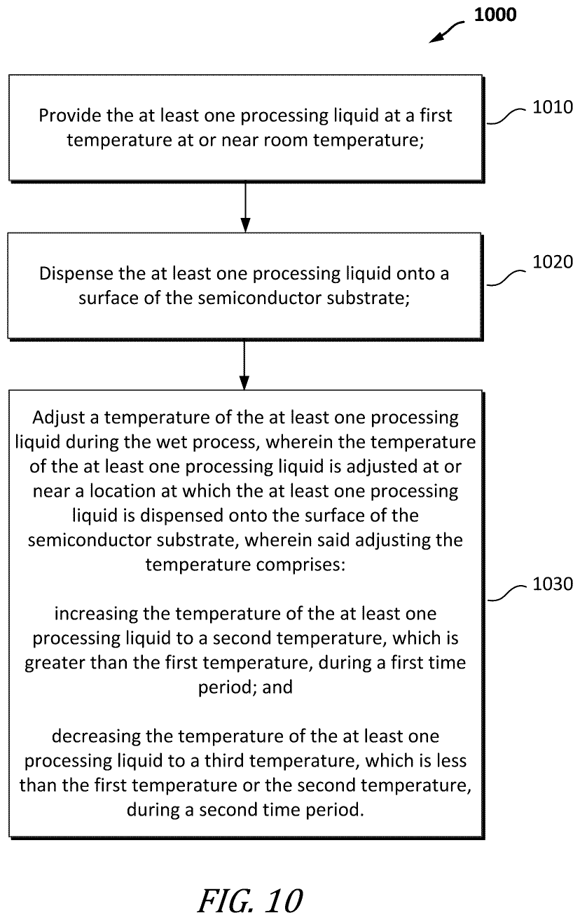

FIGS. 9-10 illustrate various embodiments of methods that utilize the techniques disclosed herein to adjust a temperature of at least one processing liquid used to process a semiconductor substrate in a wet process. It will be recognized that the embodiments of the methods shown in FIGS. 9-10 are merely exemplary and additional methods may utilize the techniques disclosed herein. Further, additional processing steps may be added to the methods shown in FIGS. 9-10 as the steps described are not intended to be exclusive. Moreover, the order of the steps is not limited to the order shown in the figures as different orders may occur and/or various steps may be performed in combination or at the same time.

In some embodiments, the methods shown in FIGS. 9-10 may be implemented using one of the chemical supply systems shown in FIGS. 3-8. It is noted, however, that the disclosed methods are not strictly limited to the example shown in FIGS. 3-8 and may be alternatively implemented using other configurations of chemical supply systems having a temperature control unit 380 as disclosed further herein.

As shown in FIG. 9, the method 900 may begin by providing the at least one processing liquid at a temperature at or near room temperature (in step 910) and dispensing the at least one processing liquid onto a surface of the semiconductor substrate (in step 920). The at least one processing liquid dispensed onto the substrate surface (in step 920) may include a wide variety of processing liquids commonly used to process a semiconductor substrate. For example, the at least one processing liquid may be an etch solution, a cleaning solution, a rinse solvent or a drying solvent. Non-exclusive examples of processing liquids are disclosed above.

The method 900 further includes supplying a hot vapor to the at least one processing liquid to increase the temperature of the at least one processing liquid above room temperature (in step 930) before or after the at least one processing liquid is dispensed onto the surface of the semiconductor substrate (in step 920). In some embodiments, the temperature of the hot vapor may be greater than or equal to its boiling point, which is higher than the temperature of the at least one processing liquid to quickly and efficiently increase the temperature of the at least one processing liquid above room temperature.

In some embodiments, the method 900 may further include generating the hot vapor supplied to the at least one processing liquid by heating a liquid to a boiling point of the liquid. A wide variety of liquids may be used to generate the hot vapor supplied to the at least one processing liquid. For example, and as noted above, the hot vapor may be generated using water, organic solvents (such as isopropyl alcohol, ethylene glycol, propylene carbonate, etc.) and other liquids commonly used in semiconductor processing. In some embodiments, the liquid used to generate the hot vapor may be the same as the at least one processing liquid. In other embodiments, the liquid used to generate the hot vapor may differ from the at least one processing liquid.

The temperature of the hot vapor may be greater than or equal to the boiling point of the liquid used to generate the hot vapor. For example, the temperature of the hot vapor may be: (a) at least 100° C. when water is used to generate the hot vapor, (b) at least 82.3° C. when isopropyl alcohol (IPA) is used to generate the hot vapor, (c) at least 197.3° C. when ethylene glycol (EG) is used to generate the hot vapor, or (d) at least 242° C. when propylene carbonate (PC) is used to generate the hot vapor.

The method 900 further includes adjusting the temperature of the at least one processing liquid during the wet process by adjusting a flow rate of the hot vapor supplied to the at least one processing liquid (in step 940). In some embodiments, the temperature of the at least one processing liquid may be increased (in step 940) by increasing the flow rate of the hot vapor. In other embodiments, the temperature of the at least one processing liquid may be decreased (in step 940) by decreasing the flow rate of the hot vapor. In some embodiments, a temperature control unit 380 as shown in FIGS. 3-7 may be used to generate the hot vapor supplied to the at least one processing liquid (in step 930) and adjust the temperature of the at least one processing liquid (in step 940).

FIG. 10 illustrates another embodiment of a method 1000 that utilizes the techniques disclosed herein to adjust a temperature of at least one processing liquid used to process a semiconductor substrate in a wet process. Similar to the method 900 shown in FIG. 9, the method 1000 shown in FIG. 10 may begin by providing the at least one processing liquid at a first temperature at or near room temperature (in step 1010) and dispensing the at least one processing liquid onto a surface of the semiconductor substrate (in step 1020). The at least one processing liquid dispensed onto the substrate surface (in step 1020) may include a wide variety of processing liquids commonly used to process a semiconductor substrate. For example, the at least one processing liquid may be an etch solution, a cleaning solution, a rinse solvent or a drying solvent. Non-exclusive examples of processing liquids are set forth above.

The method 1000 further includes adjusting a temperature of the at least one processing liquid during the wet process (in step 1030). The temperature of the at least one processing liquid is adjusted (in step 1030) at or near a location at which the at least one processing liquid is dispensed onto the surface of the semiconductor substrate (i.e., at or near the point of use). More specifically, the temperature of the at least one processing liquid is adjusted (in step 1030) by: (a) increasing the temperature of the at least one processing liquid to a second temperature, which is greater than the first temperature, during a first time period, and (b) decreasing the temperature of the at least one processing liquid to a third temperature, which is less than the first temperature or the second temperature, during a second time period. The first time period may occur before or after the second time period in the method 1000.

In some embodiments, the temperature of the at least one processing liquid may be adjusted (in step 1030) by initially increasing the temperature of the processing liquid(s) during the first time period before subsequently decreasing the temperature of the processing liquid(s) during the second time period. For example, the temperature of the processing liquid(s) may be initially increased during the first time period by supplying a hot vapor to the processing liquid(s). The temperature of the hot vapor may be significantly greater than or equal to its boiling point, which is higher than the temperature of the processing liquid(s). Once combined with the processing liquid(s), the latent heat within the hot vapor quickly and efficiently increases the temperature of the processing liquid(s) from the first temperature (e.g., room temperature) to a second temperature, which is greater than the first temperature. In some embodiments, the temperature of the processing liquid(s) may be subsequently decreased during the second time period by: (a) decreasing the flow rate of the hot vapor, or (b) ceasing the supply of the hot vapor and supplying a cold slurry to the processing liquid(s) to decrease the temperature of the processing liquid(s) from the second temperature to a third temperature, which is less than the second temperature. When a cold slurry is used, the temperature of the cold slurry may be significantly less than the second temperature to quickly and efficiently decrease the temperature of the processing liquid(s) from the second temperature to the third temperature.

In other embodiments, the temperature of the at least one processing liquid may be adjusted (in step 1030) by initially decreasing the temperature of the processing liquid(s) during the second time period before subsequently increasing the temperature of the processing liquid(s) during the first time period. For example, the temperature of the processing liquid(s) may be initially decreased during the second time period by supplying a cold slurry to the processing liquid(s). The temperature of the cold slurry may be significantly less than the temperature of the processing liquid(s). Once combined with the processing liquid(s), the latent heat within the cold slurry quickly and efficiently decreases the temperature of the processing liquid(s) from the first temperature (e.g., room temperature) to a third temperature, which is less than the first temperature. The third temperature may be less than 20° C., and in some cases, may be less than or equal to 0° C. In some embodiments, the temperature of the processing liquid(s) may be subsequently increased during the first time period by: (a) decreasing the flow rate of the cold slurry, or (b) ceasing the supply of the cold slurry and supplying a hot vapor to the processing liquid(s) to increase the temperature of the processing liquid(s) from the third temperature to a second temperature, which is greater than the third temperature. The temperature of the hot vapor may be significantly greater than or equal to its boiling point, which is higher than the third temperature to quickly and efficiently increase the temperature of the processing liquid(s) from the third temperature to the second temperature.

In some embodiments, the temperature of the at least one processing liquid may be adjusted (in step 1030) by: (a) supplying hot water to one or more additional processing liquids to increase the temperature of the at least one processing liquid to the second temperature during the first time period, and (b) supplying cold water to the one or more additional processing liquids to decrease the temperature of the at least one processing liquid to the third temperature during the second time period. A temperature of the hot water may range between about 23° C. to about 100° C., whereas a temperature of the cold water may range between about 0° C. to about 23° C. The first time period may occur before or after the second time period, as noted above.

In some embodiments, the first time period and the second time period may not overlap. If the first time period occurs before the second time period, step 1030 may further include ceasing the supply of the hot water before supplying the cold water to the one or more additional processing liquids. If the first time period occurs after the second time period, step 1030 may further include ceasing the supply of the cold water before supplying the hot water to the one or more additional processing liquids.

In some embodiments, the first time period and the second time period may at least partially overlap. In such embodiments, step 1030 may further include adjusting a flow rate of at least one of the hot water and the cold water to gradually transition the temperature of the at least one processing liquid between second temperature and the third temperature.

The techniques disclosed herein may be utilized during the processing of a wide range of substrates. The substrate may be any substrate for which the patterning of the substrate is desirable. For example, in one embodiment, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. The concepts disclosed herein may be utilized at any stage of the substrate process flow, for example any of the numerous photolithography steps which may be utilized to form a completed substrate.

In some embodiments, the techniques disclosed herein may be used to control the etch rate and improve etch selectivity during a wet process. In one example application, the techniques disclosed herein may be used to control the silicon dioxide (SiO₂) etch rate and improve the etch selectivity to an underlying silicon nitride (SiN) layer when using dilute hydrofluoric acid (dHF) to remove a SiO₂ layer overlying the SiN layer. While dHF etches both SiO₂ and SiN faster at higher chemical process temperatures, etch selectivity to SiN is improved at lower process temperatures. In some embodiments, the techniques described herein can be used to increase the temperature of the dHF supplied to the SiO₂ surface to increase the SiO₂ etch rate until the SiO₂ layer is almost removed, before decreasing the temperature of the dHF to remove any remaining SiO₂ and expose the underlying SiN layer. Decreasing the temperature of the etch solution near the end of the SiO₂ etch decreases the etch rate and improves the selectivity to SiN.

Systems and methods for processing a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for adjusting a temperature of at least one processing liquid used to process a semiconductor substrate in a wet process, the method comprising:
providing the at least one processing liquid at a temperature at or near room temperature;
dispensing the at least one processing liquid onto a surface of the semiconductor substrate;
supplying a hot vapor to the at least one processing liquid to increase the temperature of the at least one processing liquid above room temperature before or after the at least one processing liquid is dispensed onto the surface of the semiconductor substrate, wherein a temperature of the hot vapor is greater than or equal to its boiling point, which is higher than the temperature of the at least one processing liquid; and
adjusting the temperature of the at least one processing liquid during the wet process by adjusting a flow rate of the hot vapor supplied to the at least one processing liquid.

2. The method of claim 1, wherein said adjusting the temperature comprises increasing the flow rate of the hot vapor to increase the temperature of the at least one processing liquid.

3. The method of claim 1, wherein said adjusting the temperature comprises decreasing the flow rate of the hot vapor to decrease the temperature of the at least one processing liquid.

4. The method of claim 1, further comprising generating the hot vapor by heating a liquid to a boiling point of the liquid.

5. The method of claim 4, wherein the liquid used to generate the hot vapor is water, and wherein the temperature of the hot vapor is at least 100° C.

6. The method of claim 4, wherein the liquid used to generate the hot vapor is an organic solvent, and wherein the temperature of the hot vapor is greater than or equal to the boiling point of the organic solvent.

7. The method of claim 4, wherein the liquid used to generate the hot vapor is the same as the at least one processing liquid.

8. The method of claim 4, wherein the liquid used to generate the hot vapor differs from the at least one processing liquid.

9. The method of claim 4, wherein the at least one processing liquid comprises an etch solution, a cleaning solution, a rinse solvent or a drying solvent.

10. A method for adjusting a temperature of at least one processing liquid used to process a semiconductor substrate in a wet process, the method comprising:
providing the at least one processing liquid at a first temperature at or near room temperature;
dispensing the at least one processing liquid onto a surface of the semiconductor substrate;
adjusting a temperature of the at least one processing liquid during the wet process, wherein the temperature of the at least one processing liquid is adjusted at or near a location at which the at least one processing liquid is dispensed onto the surface of the semiconductor substrate, wherein said adjusting the temperature comprises:
increasing the temperature of the at least one processing liquid to a second temperature, which is greater than the first temperature, during a first time period; and
decreasing the temperature of the at least one processing liquid to a third temperature, which is less than the first temperature or the second temperature, during a second time period.

11. The method of claim 10, wherein said adjusting the temperature comprises initially increasing the temperature of the at least one processing liquid during the first time period before subsequently decreasing the temperature of the at least one processing liquid during the second time period.

12. The method of claim 11, wherein said increasing the temperature of the at least one processing liquid comprises:
supplying a hot vapor to the at least one processing liquid to increase the temperature of the at least one processing liquid from the first temperature to the second temperature, wherein a temperature of the hot vapor is greater than or equal to its boiling point, which is higher than the first temperature.

13. The method of claim 12, wherein said decreasing the temperature of the at least one processing liquid comprises:
decreasing a flow rate of the hot vapor to decrease the temperature of the at least one processing liquid from the second temperature to the third temperature, which is less than the second temperature.

14. The method of claim 12, wherein said decreasing the temperature of the at least one processing liquid comprises:
ceasing the supply of the hot vapor to the at least one processing liquid; and
supplying a cold slurry to the at least one processing liquid to decrease the temperature of the at least one processing liquid from the second temperature to the third temperature, which is less than the second temperature, wherein a temperature of the cold slurry is less than the second temperature.

15. The method of claim 10, wherein said adjusting the temperature comprises initially decreasing the temperature of the at least one processing liquid during the second time period before subsequently increasing the temperature of the at least one processing liquid during the first time period.

16. The method of claim 15, wherein said decreasing the temperature of the at least one processing liquid comprises:
supplying a cold slurry to the at least one processing liquid to decrease the temperature of the at least one processing liquid from the first temperature to the third temperature, which is less than the first temperature, wherein a temperature of the cold slurry is less than the first temperature.

17. The method of claim 16, wherein the cold slurry is generated by freezing water to generate a mixture of frozen water solids suspended in water, and wherein the third temperature ranges between 20° C. to 0° C.

18. The method of claim 16, wherein the cold slurry is generated by freezing an organic solvent and water mixture to generate frozen solids of the organic solvent and water mixture suspended in the organic solvent and water mixture, and wherein the third temperature is less than or equal to 0° C.

19. The method of claim 16, wherein the cold slurry is generated by freezing an organic solvent to generate frozen solids of the organic solvent suspended in the organic solvent, and wherein the third temperature is less than 0° C.

20. The method of claim 16, wherein said increasing the temperature of the at least one processing liquid comprises:
ceasing the supply of the cold slurry to the at least one processing liquid; and
supplying a hot vapor to the at least one processing liquid to increase the temperature of the at least one processing liquid from the third temperature to the second temperature, which is greater than the third temperature, wherein a temperature of the hot vapor is greater than or equal to its boiling point, which is higher than the third temperature.
